(19) United States
(12) Patent Application Publication
(10) Pub. No.: US 2007/0095087 A1
(43) Pub. Date: May 3, 2007

(54) Vapor compression cooling system for cooling electronics

(76) Inventors: Michael J. Wilson, Racine, WI (US); Jonathan P. Wattelet, Gurnee, IL (US); Jianmin Yin, Kenosha, WI (US)

Correspondence Address: WOOD, PHILLIPS, KATZ, CLARK & MORTIMER, 500 W. MADISON STREET, SUITE 3800, CHICAGO, IL, 60661, US

(21) Appl. No.: 11/264,406

(22) Filed: Nov. 1, 2005

(51) Int. Cl. F25D 23/12; F25B 41/00; H05K 7/20

(52) U.S. Cl. 62/259.2; 62/513; 361/702

(57) ABSTRACT

A vapor compression cooling system and method (10) is provided for cooling one or more microprocessors (12,14) via one or more cold plates (22,24) mated with the microprocessor(s). Each cold plate (22,24) includes an evaporator (32,34), and the cooling system (10) is designed to operate such that the quality of the refrigerant exiting the evaporator(s) (32,34) is less than 100% so as to maximize the cooling ability of the cold plate(s) (22,24), i.e., to avoid dry-out of the evaporator(s) (32,34). A suction line heat exchanger (26) is provided to protect the compressor (16) of the system (10) by increasing the quality of the refrigerant from the evaporator to at least 100% so as to provide vapor phase refrigerant to the compressor (16).

### FIELD OF THE INVENTION

This invention relates to cooling systems for electronics, and more particularly to vapor compression cooling systems for cooling at least one microprocessor.

### BACKGROUND OF THE INVENTION

There is currently an ever-increasing demand to improve the processing speed, power, and memory of electronic devices, such as desktop computers, laptop or portable computers, hand-held computers, cellular phones, and such, while decreasing the overall size and weight of such devices. To this end, more powerful microprocessors are constantly being developed in smaller and smaller packages, but with increasing demands for heat rejection to remove the heat generated from the increased processing power and speed. To overcome challanges associated with heat rejection, a number of active cooling systems have been proposed for cooling microprocessors, and while many of these systems may prove adequate for this intended use, there is always room for improvement.

### SUMMARY OF THE INVENTION

According to one feature of the invention, a vapor compression cooling system is provided for cooling at least one microprocessor. The cooling system includes a compressor to pressurize a refrigerant used in the cooling system, a condenser to condense pressurized refrigerant received from the compressor, an expansion device to expand pressurized refrigerant received from the condenser, and a cold plate. The cold plate includes a surface that mates with a heat rejecting surface of a corresponding microprocessor, and an evaporator to receive expanded refrigerant from the expansion device, transfer heat from the corresponding microprocessor to the expanded refrigerant, and return heated refrigerant back to the system with a quality of less than 100%. The cooling system further includes a suction line heat exchanger to receive heated refrigerant from the evaporator at a quality of less than 100% and transfer heat from the pressurized refrigerant to the heated refrigerant to provide refrigerant at a quality of at least 100% back to the compressor.

According to one feature, the suction line heat exchanger is located downstream from the condenser with respect to the refrigerant flow through the system to receive the pressurized refrigerant from the condenser.

In one feature, the suction line heat exchanger is located upstream from the condenser with respect to the refrigerant flow through the system to deliver the pressurized refrigerant to the condenser.

In accordance with one feature, the cooling system includes another cold plate including a surface that mates with a heat rejecting surface of a corresponding microprocessor and an evaporator to receive expanded refrigerant from the expansion device, transfer heat from the corresponding microprocessor to the expanded refrigerant, and return heated refrigerant back to the system with a quality of less than 100%.

According to one feature of the invention, a method is provided for operating a vapor compression cooling system to cool at least one microprocessor. The method includes the steps of compressing a refrigerant to provide pressurized refrigerant to the system, condensing the pressurized refrigerant to provide condensed refrigerant to the system, expanding the condensed refrigerant to provide cooled refrigerant to the system, transferring heat from a microprocessor to the cooled refrigerant to provide heated refrigerant with a quality of less than 100% to the system, and transferring additional heat from the pressurized refrigerant to the heated refrigerant to provide refrigerant with a quality of at least 100% to the system for use in the step of compressing.

In accordance with one feature of the invention, a method is provided for operating a vapor compression cooling system to cool at least one microprocessor. The method includes the steps of compressing a refrigerant to provide pressurized refrigerant to the system, condensing the pressurized refrigerant to provide condensed refrigerant to the system, expanding the condensed refrigerant to provide cooled refrigerant to the system, transferring heat from a microprocessor to the cooled refrigerant to provide heated refrigerant with a quality of less than 100% to the system, and transferring additional heat from the condensed refrigerant to the heated refrigerant to provide refrigerant with a quality of at least 100% to the system for use in the step of compressing.

Other objects, features, and advantages of the invention will become apparent from a review of the entire specification, including the appended claims and drawings.

### BRIEF DESCRIPTION OF THE DRAWINGS

FIG. 1 is a diagrammatic representation of a cooling system embodying the present invention;

FIG. 2 is a refrigerant pressure vs. enthalpy diagram representing operation of the system of FIG. 1;

FIG. 3 is a diagrammatic representation of another vapor compression cooling system embodying the present invention; and

FIG. 4 is a refrigerant pressure vs. enthalpy diagram representing operation of the system of FIG. 3.

### DETAILED DESCRIPTION OF THE PREFERRED EMBODIMENTS

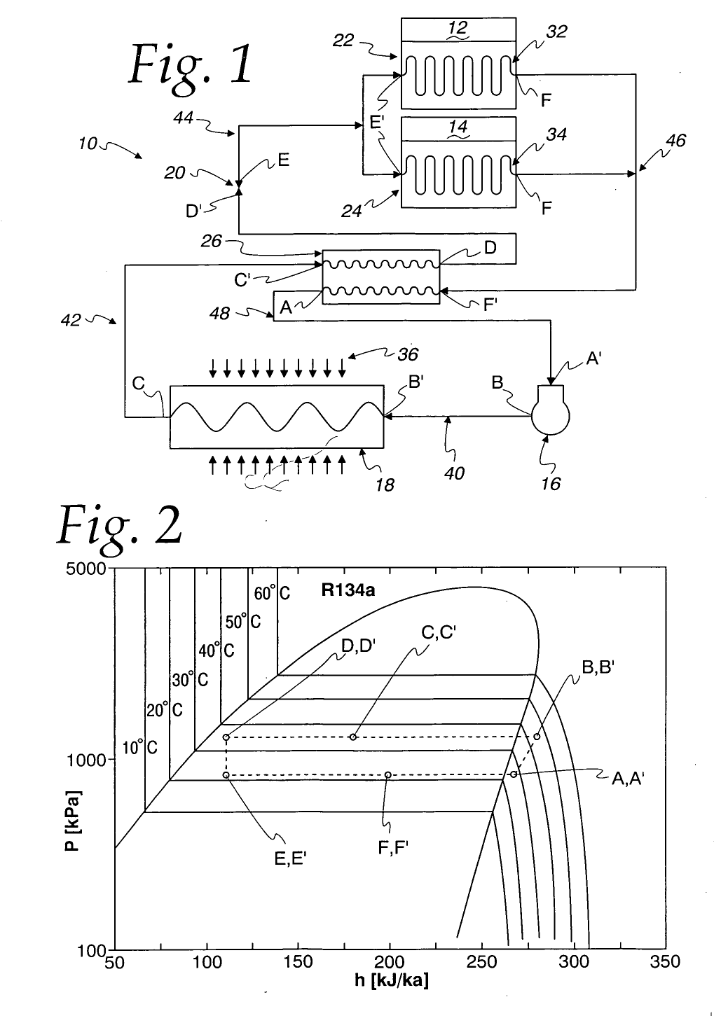

With reference to FIG. 1, a vapor compression cooling system and method 10 are provided for cooling one or more microprocessors, such as the microprocessor shown schematically at 12 and the microprocessor shown schematically at 14. The cooling system utilizes a suitable refrigerant, such as R134a, which is circulated through the cooling system via pressurization provided by a compressor 16, which is preferably an electric motor driven compressor with speed control. The cooling system further includes a condenser 18, an expansion device 20, a pair of cold plates 22 and 24, each associated with a corresponding one of the microprocessor 12 and 14, and a suction line heat exchanger (SLHX) 26. Each of the cold plates 22 and 24 includes a surface 28 and 30 that mates with the corresponding microprocessor 12 and 14, and an evaporator, shown schematically at 32 and 34, that receives heat generated by the corresponding microprocessor 12, 14. One typical footprint for a microprocessor 12 or 14 would be a rectangular footprint with a width of 13 mm and a length of 9 mm, with a heat rejection of 175 watts. While each of the above components of the system 10 must be correctly sized for the required cooling of one or more of the microprocessors 12, 14, which will typically mean miniaturization in comparison to conventional household or automotive type vapor compression cooling systems, there are many known and suitable forms for each of the components and the details of such components will depend greatly upon the parameters of each particular application for which the cooling system 10 is used. Accordingly, further details of the precise construction and/or form of each of the components will not be given herein.

Reference herein will be made to the “quality of the refrigerant” or just the “quality”. Quality is as conventionally defined, namely, the weight ratio % of the mass of refrigerant in the vapor phase to the total mass of the refrigerant, i.e., the combined mass of liquid refrigerant and vapor refrigerant, at a given point in the system. Thus, refrigerant wholly in the vapor phase will have a quality of 100%, while refrigerant wholly in the liquid phase will have a quality of 0%. Refrigerant that is both in the liquid and vapor phase will have a quality greater than 0% and less than 100%, the exact number being determined by the ratio of refrigerant vapor to total refrigerant.

The system 10 is designed to operate such that the quality of the refrigerant exiting the evaporator(s) 32, 34 is less than 100% so as to maximize the cooling ability of the cold plate(s) 22,24, i.e., to avoid dry-out of the evaporator(s) 32,34. The suction line heat exchanger 26 is provided to protect the compressor 16 by increasing the quality of the refrigerant from the evaporator to at least 100% (and preferably in a superheated state) so as to provide vapor phase refrigerant to the compressor 16. As used herein, the phrase “a quality of at least 100%” is intended to mean that the refrigerant is at 100% quality or is in a superheated vapor state.

In operation, the compressor 16 compresses the refrigerant to provide pressurized refrigerant to the system 10, as shown schematically by the line 40. The condenser 18 receives the pressurized refrigerant from the compressor 20 and transfers heat to a coolant flow 36 (preferably an air flow) so as to provide condensed refrigerant to the system, as shown schematically by the lines 42. The expansion device 20 expands the condensed, pressurized refrigerant received from the condenser 18 to provide cooled refrigerant to the system, as shown schematically by the lines 44. The cooled refrigerant is directed to the evaporator(s) 32,34 wherein heat is transferred from the microprocessor(s) 12,14 to the cooled refrigerant to provide heated refrigerant with a quality of less than 100% to the system, as shown schematically by the lines 46. The heated refrigerant is directed to the suction line heat exchanger 26 wherein heat is transferred from the condensed refrigerant (which has also been directed to the suction line heat exchanger 26 downstream from the condenser 18 and upstream from the expansion device 20) to the heated refrigerant so as to provide refrigerant at 100% quality back to the compressor 16, as shown schematically by the lines 48.

The pressure and enthalpy of the refrigerant as it moves through the system is illustrated in FIG. 2 (assumes a ideal system) with the points A, A′; B, B′; C, C′: D, D′; E, E′; and F, F′ on the diagram corresponding to the like lettered locations in the system 10 of FIG. 1.

As a working example of the system 10 of FIGS. 1 and 2, the refrigerant provided from the expansion device 20 to the evaporator(s) 32,34 could have an entrance quality of around 16.2% and the refrigerant provided from the evaporator(s) 32,34 to the system could have an exit quality of around 65%, with the refrigerant provided from the suction line heat exchanger 26 back to the compressor 16 having a super heat of approximately 5° C.

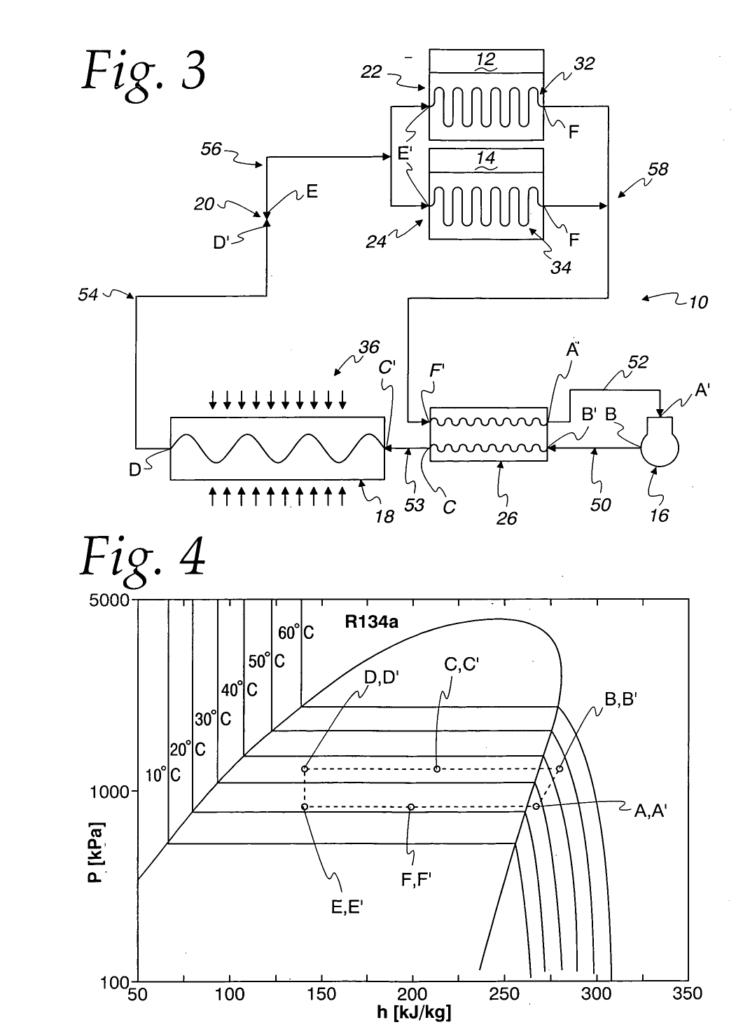

The vapor compression cooling system 10 of FIG. 3 is similar to the system 10 of FIG. 1 with like numbers indicating like components, except for the location of the suction line heat exchanger 26, which is shown located upstream of the condenser 18 in FIG. 3 rather than downstream from the condenser 18 such as in the system 10 of FIG. 1. As with the system 10 of FIG. 1, the system 10 of FIG. 3 is designed to operate such that the quality of the refrigerant exiting the evaporator(s) 32, 34 is less than 100% so as to maximize the cooling ability of the cold plate(s) 22,24, i.e., to avoid dry-out of the evaporator(s) 32,34. The suction line heat exchanger 26 is provided to protect the compressor 16 by increasing the quality of the refrigerant from the evaporator to 100% so as to provide vapor phase refrigerant to the compressor 16.

Accordingly, for the system 10 of FIG. 3, the suction line heat exchanger 26 receives pressurized refrigerant from the compressor 16, as shown schematically by the line 50, and transfers heat from the pressurized refrigerant to the heated refrigerant received from the evaporator(s) 32,34 to provide refrigerant at 100% quality back to the compressor 16, such as shown schematically by the line 52. The pressurized refrigerant is then directed from the suction line heat exchanger 26 to the condenser 18, such as shown schematically by the line 53, so the condenser 18 can transfer heat from the pressurized refrigerant to a coolant flow 36, such as an air flow, to provide condensed, pressurized refrigerant to the system 10, such as shown schematically by the lines 54. The expansion device 20 receives the condensed, pressurized refrigerant from the condenser 18 and expands the refrigerant to provide cooled refrigerant to the system 10, such as shown schematically by the lines 36. The expanded, cooled refrigerant is directed to the evaporator(s) 32,34 wherein heat is transferred from the microprocessor(s) 12,14 to the refrigerant to provide heated refrigerant back to the system with a quality of less than 100%, as shown schematically by the lines 58.

Again, FIG. 4 is a pressure-enthalpy diagram for the refrigerant as it passes through the system 10 of FIG. 3 (assuming ideal system), with the letters A, A′; B, B′; C, C′; D, D′; E, E′; and F, F′ in the diagram of FIG. 4 corresponding to the like lettered locations in the system 10 of FIG. 3.

As a working example of the system 10 of FIGS. 3 and 4, the refrigerant provided from the expansion device 20 to the evaporator(s) 32,34 could have an entrance quality of around 34.1% and the refrigerant provided from the evaporator(s) 32,34 to the system could have an exit quality of around 65%, with the refrigerant provided from the suction line heat exchanger 26 back to the compressor 16 having a super heat of approximately 5° C.

While there are many possible control schemes that could be utilized in the systems 10 of FIGS. 1-4 to insure that the exit quality from the evaporator(s) 32,34 is less than 100%, in one preferred form, the speed of the compressor is controlled via the speed of an electric compressor drive motor (not shown) using any suitable motor speed control in response to selected system parameters that are monitored using suitable sensors or probes (not shown). For example, the exit temperatures of the refrigerant at points A and D in FIGS. 1 and 2, and points A and C in FIGS. 3 and 4 could be monitored and compared to suitable set points that would yield the desired exit quality from the evaporator(s) 32,34, with the speed of the compressor being increased or decreased to maintain the monitored temperatures within a suitable range of the set points. By way of another example, a temperature sensor 60 could be used to sense the exit temperature from the low pressure side of the suction line heat exchanger 26 with the sensed temperature then being used to control a thermal expansion valve, when the expansion device 20 is provided in that form. In such a system, it may be preferred to include a receiver in the high pressure flow path between the condenser 36 and the suction line heat exchanger 26, with the potential for this receiver to be an integrated portion of the condenser 36. As yet another example, when the expansion device 20 is provided in the form of a fixed orifice, it may be desirable for the suction line heat exchanger 26 to include a liquid accumulation function.

While the systems 10 of FIGS. 1-4 have been shown herein as having two cold plates 22 and 24, each cooling a corresponding one of the microprocessors 12 and 14, it should be understood that the systems 10 could be configured with only a single cold plate or more than two cold plates, and that any given cold plate could be dedicated to cooling a single microprocessor or multiple microprocessors.

It should be appreciated that by providing a suction line heat exchanger 26 in a vapor compression cooling system 10 wherein the exit quality from the evaporator(s) 32,34 of the cooling plate(s) 22,24 is always maintained at less than 100%, the system 10 can provide optimal cooling of the microprocessor(s) 12,14 while protecting the compressor 16 from damage by providing refrigerant to the compressor with a quality of 100%.

1. A vapor compression cooling system for cooling at least one microprocessor, the cooling system comprising:
a compressor to pressurize a refrigerant used in the cooling system;
a condenser to condense pressurized refrigerant received from said compressor;
an expansion device to expand pressurized refrigerant received from said condenser;
a cold plate comprising
a surface that mates with a heat rejecting surface of a corresponding microprocessor, and
an evaporator to receive expanded refrigerant from said expansion device and to transfer heat from said corresponding microprocessor to said expanded refrigerant and return heated refrigerant back to the system with a quality of less than 100%; and
a suction line heat exchanger to receive heated refrigerant from said evaporator at a quality of less than 100% and transfer heat from said pressurized refrigerant to said heated refrigerant to provide refrigerant at a quality of at least 100% back to said compressor.

2. The cooling system of claim 1 further comprising another cold plate, said another cold plate comprising
a surface that mates with a heat rejecting surface of a corresponding microprocessor, and
an evaporator to receive expanded refrigerant from said expansion device and to transfer heat from said corresponding microprocessor to said expanded refrigerant and return heated refrigerant back to the system with a quality of less than 100%.

3. A vapor compression cooling system for cooling at least one microprocessor, the cooling system comprising:
a compressor to pressurize a refrigerant used in the cooling system;
a condenser to condense pressurized refrigerant received from said compressor;
an expansion device to expand pressurized refrigerant received from said condenser;
a cold plate comprising
a surface that mates with a heat rejecting surface of a corresponding microprocessor, and
an evaporator to receive expanded refrigerant from said expansion device and to transfer heat from said corresponding microprocessor to said expanded refrigerant and return heated refrigerant back to the system with a quality of less than 100%; and
a suction line heat exchanger to receive heated refrigerant from said evaporator at a quality of less than 100% and transfer heat from said pressurized refrigerant to said heated refrigerant to provide refrigerant at a quality of at least 100% back to said compressor, said suction line heat exchanger being located downstream from said condenser with respect to the refrigerant flow through the system to receive said pressurized refrigerant from said condenser.

4. The cooling system of claim 3 further comprising another cold plate,
said another cold plate comprising
a surface that mates with a heat rejecting surface of a corresponding microprocessor, and
an evaporator to receive expanded refrigerant from said expansion device and to transfer heat from said corresponding microprocessor to said expanded refrigerant and return heated refrigerant back to the system with a quality of less than 100%.

5. A vapor compression cooling system for cooling at least one microprocessor, the cooling system comprising:
a compressor to pressurize a refrigerant used in the cooling system;
a condenser to condense pressurized refrigerant received from said compressor;
an expansion device to expand pressurized refrigerant received from said condenser;
a cold plate comprising
a surface that mates with a heat rejecting surface of a corresponding microprocessor, and
an evaporator to receive expanded refrigerant from said expansion device and to transfer heat from said corresponding microprocessor to said expanded refrigerant and return heated refrigerant back to the system with a quality of less than 100%;
and
a suction line heat exchanger to receive heated refrigerant from said evaporator at a quality of less than 100% and transfer heat from said pressurized refrigerant to said heated refrigerant to provide refrigerant at a quality of at least 100% back to said compressor, said suction line heat exchanger being located upstream from said condenser with respect to the refrigerant flow through the system to deliver said pressurized refrigerant to said condenser.

6. The cooling system of claim 6 further comprising another cold plate,
said another cold plate comprising
a surface that mates with a heat rejecting surface of a corresponding microprocessor, and
an evaporator to receive expanded refrigerant from said expansion device and to transfer heat from said corresponding microprocessor to said expanded refrigerant and return heated refrigerant back to the system with a quality of less than 100%.

7. A method of operating a vapor compression cooling system to cool at least one microprocessor, said method comprising the steps of:
compressing a refrigerant to provide pressurized refrigerant to the system;
condensing said pressurized refrigerant to provide condensed refrigerant to the system;
expanding said condensed refrigerant to provide cooled refrigerant to the system;
transferring heat from a microprocessor to the cooled refrigerant to provide heated refrigerant with a quality of less than 100% to the system; and
transferring additional heat from said pressurized refrigerant to said heated refrigerant to provide refrigerant with a quality of at least 100% to the system for use in said step of compressing.

8. A method of operating a vapor compression cooling system to cool at least one microprocessor, said method comprising the steps of:
compressing a refrigerant to provide pressurized refrigerant to the system;
condensing said pressurized refrigerant to provide condensed refrigerant to the system;
expanding said condensed refrigerant to provide cooled refrigerant to the system;
transferring heat from a microprocessor to the cooled refrigerant to provide heated refrigerant with a quality of less than 100% to the system; and
transferring additional heat from said condensed refrigerant to said heated refrigerant to provide refrigerant with a quality of at least 100% to the system for use in said step of compressing.
